(19) United States
(12) Patent Application Publication
(10) Pub. No.: US 2006/0043457 A1
(43) Pub. Date: Mar. 2, 2006

(54) Nonvolatile semiconductor memory device having a recessed gate and a charge trapping layer and methods of forming the same, and methods of operating the same

(76) Inventor: Seung-Jae Baik, Gyeonggi-do (KR)

Correspondence Address: MYERS BIGEL SIBLEY & SAJOVEC, PO BOX 37428, RALEIGH, NC, 27627, US

(21) Appl. No.: 11/209,935

(22) Filed: Aug. 23, 2005

(30) Foreign Application Priority Data
Sep. 2, 2004 (KR) 2004-69865

(51) Int. Cl. H01L 29/76

(52) U.S. Cl. 257/314

(57) ABSTRACT

A nonvolatile semiconductor memory device includes a substrate having a trench therein, a gate electrode in the trench, and a plurality of source/drain regions in the substrate adjacent the gate electrode. A pair of channel regions extends along sidewalls of the trench between respective pairs of adjacent source/drain regions. A charge trapping layer is between the gate electrode and the channel regions, and an insulation layer is between the charge trapping layer and the channel regions. Methods of forming nonvolatile semiconductor memory devices include forming a recess in a substrate, forming a first source/drain region beneath the recess, and forming a second source/drain region and a third source/drain region at an upper portion of the substrate on opposing sides of the recess and spaced apart from the first source/drain region. An insulation structure in the recess includes first and second insulation layers and a charge trapping layer between the first and the second insulation layers. Methods of operating nonvolatile semiconductor memory device are also disclosed.

### CROSS-REFERENCE TO RELATED APPLICATION

This application claims priority under 35 USC § 119 from Korean Patent Application No. 2004-69865 filed on Sep. 2, 2004, the contents of which are incorporated herein by reference in their entirety.

### FIELD OF THE INVENTION

The present invention relates to nonvolatile semiconductor memory devices, methods of forming nonvolatile semiconductor memory devices, and methods of operating nonvolatile semiconductor memory devices. In particular, the present invention relates to nonvolatile semiconductor memory devices having a charge trapping layer, methods of forming nonvolatile semiconductor memory devices having a charge trapping layer, and a methods of operating nonvolatile semiconductor memory devices having a charge trapping layer.

### BACKGROUND OF THE INVENTION

Semiconductor memory devices may generally be classified as volatile semiconductor memory devices or nonvolatile semiconductor memory devices. Volatile semiconductor memory devices such as dynamic random access memory (DRAM) devices and/or static random access memory (SRAM) devices may have relatively rapid response speeds. However, volatile semiconductor memory devices lose data stored therein when applied power is shut off. Although nonvolatile semiconductor devices, such as electrically erasable programmable read only memory (EEPROM) devices and/or flash memory devices, may have relatively slow response speeds, nonvolatile semiconductor memory devices can maintain data stored therein when applied power is shut off. In EEPROM devices, data may be electrically stored (i.e., programmed) or erased through a Fowler-Nordheim (F-N) tunneling mechanism and/or a channel hot electron injection mechanism. Flash memory devices may typically have a floating gate construction or a SONOS construction.

U.S. Pat. No. 5,834,808 issued to Tsukiji discloses a flash memory device that has one control gate and two floating gates. Additionally, U.S. Pat. No. 6,649,972 issued to Eitan provides a two bit memory cell of a flash memory device that includes two diffusion regions formed in a substrate, a channel region formed between the diffusion regions, and an oxide/nitride/oxide (ONO) layer. U.S. Pat. No. 6,649,972 discloses an ONO layer having a first oxide film, a nitride film and a second oxide film, wherein the nitride film has a thickness of below about 100 Å and includes two charge storage regions.

As appreciated by the present inventor however, the flash memory devices described in the aforementioned U.S. patents may not have sufficiently high data storage density because the floating gates and/or the nitride films disclosed therein are horizontal relative to the substrate.

### SUMMARY OF THE INVENTION

Some embodiments of the invention may provide nonvolatile semiconductor memory devices having enhanced data storage density and/or reduced cell size. Moroever, some embodiments of the invention may provide methods of forming nonvolatile semiconductor devices having enhanced data storage density and/or smaller cells, and some embodiments of the invention may provide methods of operating nonvolatile semiconductor devices having enhanced data storage density.

A nonvolatile semiconductor memory device according to some embodiments of the invention includes a substrate having a trench therein, a gate electrode in the trench, and a plurality of source/drain regions in the substrate adjacent to the gate electrode. A pair of channel regions extends along sidewalls of the trench between respective pairs of adjacent source/drain regions. A charge trapping layer is disposed between the gate electrode and the channel regions, and a first insulation layer is disposed between the charge trapping layer and the channel regions.

According to some embodiments of the invention, the source/drain regions include a first source/drain region beneath the trench, a second source/drain region adjacent to a first side of the trench and vertically separated from the first source/drain region, and a third source/drain region adjacent to a second side of the trench and vertically separated from the first source/drain region.

The pair of channel regions may include a first channel between the first source/drain region and the second source/drain region, and a second channel between the first source/drain region and the third source/drain region. The charge trapping layer may include a plurality of charge storage regions.

In some embodiments of the invention, a second insulation layer may be between the gate electrode and the charge trapping layer.

A nonvolatile semiconductor memory device according to further embodiments of the invention includes a substrate having a recess therein, a first source/drain region in the substrate beneath the recess, a second source/drain region and a third source/drain region in the substrate disposed on opposing sides of the recess and spaced apart from the first source/drain region. An insulation structure is on the bottom and the opposing sides of the recess and includes a first insulation layer, a second insulation layer, and a charge trapping layer between the first insulation layer and the second insulation layer. A gate electrode is on the insulation structure.

Devices according to some embodiments of the invention may include a first channel in the substrate between the first and the second source/drain regions, and a second channel in the substrate between the first and the third source/drain regions. The charge trapping layer may include two charge storage regions adjacent to the first channel and two charge storage regions adjacent to the second channel.

In some embodiments of the invention, the charge trapping layer may include a first charge storage region adjacent to the first channel and the second source/drain region, a second charge storage region adjacent to the first channel and the first source/drain region, a third charge storage region adjacent to the second channel and the third source/drain region, and a fourth charge storage region adjacent to the second channel and the first source/drain region.

In some embodiments of the invention, the charge trapping layer may be at least partially positioned between the opposing sides of the recess and the gate electrode. Further, the charge trapping layer may extends down a first side of the recess, along the bottom of the recess, and up a second side of the recess.

In some embodiments of the invention, the gate electrode may have a rectangular prism structure that extends vertically in relation to a surface of the substrate.

In devices according to some embodiments of the invention, the first insulation layer may include silicon oxide, and the second insulation layer may include silicon oxide and/or aluminum oxide. The charge trapping layer may include silicon nitride, a nano-crystalline material, aluminum oxide and/or hafnium oxide. Furthermore, the nano-crystalline material includes silicon, silicon germanium, tungsten, cobalt, molybdenum, cadmium selenium and/or tungsten nitride. The gate electrode may include a metal and/or polysilicon doped with impurities.

In some embodiments of the invention, the substrate may have a P-type conductivity, the first source/drain region may have an N-type conductivity, the second source/drain region may have an N-type conductivity, and the third source/drain region may have an N-type conductivity.

A nonvolatile semiconductor memory device according to still further embodiments of the invention may include a gate electrode, a plurality of source/drain regions disposed adjacent to the gate electrode, a channel between an adjacent pair of source/drain regions, a charge trapping layer disposed between the gate electrode and the channel and configured to trap electrons passing through the channel, and a first insulation layer between the charge trapping layer and the channel.

In these embodiments, the gate electrode may be vertically buried at an upper portion of a substrate, and the source/drain regions may include a first source/drain region adjacent to a lower portion of the gate electrode, a second source/drain region adjacent to a first side of the gate electrode and vertically separated from the first source/drain region, and a third diffusion region adjacent to a second side of the gate electrode and vertically separated from the first source/drain region.

Methods of forming nonvolatile semiconductor memory devices according to some embodiments of the invention include forming a recess in a substrate, forming a first source/drain region beneath the recess, and forming a second source/drain region and a third source/drain region at an upper portion of the substrate on opposing sides of the recess and spaced apart from the first source/drain region. An insulation structure formed on the bottom and the opposing sides of the recess includes a first insulation layer, a second insulation layer on the first insulation layer, and a charge trapping layer between the first and the second insulation layers. A gate electrode is formed on the insulation structure.

In some embodiments of the invention, forming the recess may include forming a mask pattern having an opening therein exposing a portion of the substrate, and anisotropically etching the exposed portion of the substrate using the mask pattern as an etching mask.

According to some embodiments of the invention, forming the first source/drain region may include implanting impurities into a region of the substrate beneath the recess using the mask pattern as an implantation mask. Further, the substrate may be isotropically etched after forming the first source/drain region.

In some embodiments of the invention, forming the recess includes removing the mask pattern, forming a sacrificial layer on the substrate to fill up the recess, and partially removing the sacrificial layer until the substrate is exposed.

In some embodiments of the invention, the second and the third source/drain regions may be formed by implanting impurities into the substrate after partially removing the sacrificial layer.

In further embodiments of the invention, forming the insulation structure may include forming the first insulation layer on the bottom and the sides of the recess, forming the charge trapping layer on the first insulation layer, and forming the second insulation layer on the charge trapping layer.

In some embodiments of the invention, a portion of the charge trapping layer formed at the bottom of the recess may be removed, for example by anisotropically etching the charge trapping layer. The first insulation layer may be oxidized to repair damage to the first insulation layer caused by anisotropically etching the charge trapping layer.

In some embodiments of the invention, the first insulation layer may be formed using silicon oxide, the second insulation layer may be formed using silicon oxide and/or aluminum oxide, and/or the charge trapping layer may be formed using silicon nitride, a nano-crystalline material, aluminum oxide and/or hafnium oxide. Suitable nano-crystalline materials may include silicon, silicon germanium, tungsten, cobalt, molybdenum, cadmium selenium and/or tungsten nitride.

Methods of operating a nonvolatile semiconductor memory device according to some embodiments of the invention include programming a first data bit or a second data bit by applying different programming voltages to a gate electrode, a first source/drain region and a second source/drain region, programming a third data bit or a fourth data bit by applying different programming voltages to the gate electrode, the first source/drain region and a third source/drain region, reading the first data bit or the second data bit by applying different reading voltages to the gate electrode, the first source/drain region and the second source/drain region, reading the third data bit or the fourth data bit by applying different reading voltages to the gate electrode, the first source/drain region and the third source/drain region, and erasing a programmed data bit by applying a first erasing voltage to the gate electrode and a second erasing voltage to the first source/drain region, the second source/drain region and the third source/drain region.

According to some embodiments of the invention, the first data bit may be programmed into a charge storage region of a charge trapping layer adjacent to the second source/drain region by applying the different programming voltages to the gate electrode and the second source/drain region and by grounding the first source/drain region. The third source/drain region may be grounded while programming the first data bit.

In methods according to some embodiments of the invention, the second data bit may be programmed into a charge storage region of the charge trapping layer adjacent to the first source/drain region by applying the different programming voltages to the gate electrode and the first source/drain region and by grounding the second source/drain region. In addition, a voltage similar to the programming voltage applied to the first source/drain region may be applied to the third source/drain region while programming the second data bit.

In some embodiments of the invention, the third data bit may be programmed into a charge storage region of the charge trapping layer adjacent to the third source/drain region by applying the different programming voltages to the gate electrode and the third source/drain region and by grounding the first source/drain region. Further, the second source/drain region may be grounded while programming the third data bit.

In some methods according to the invention, the fourth data bit may be programmed into a charge storage region of the charge trapping layer adjacent to the first source/drain region by applying the different programming voltages to the gate electrode and the first source/drain region and by grounding the third source/drain region. In addition, a voltage similar to the programming voltage applied to the first source/drain region may be applied to the second source/drain region while programming the fourth data bit.

In some embodiments of the invention, the first data bit stored in the charge storage region of the charge trapping layer adjacent to the second source/drain region may be read by applying different reading voltages to the gate electrode and the first source/drain region and by grounding the second source/drain region. A voltage similar to the reading voltage applied to the first source/drain region may be applied to the third source/drain region while reading the first data bit. The second data bit stored in the charge storage region of the charge trapping layer adjacent to the first source/drain region may be read by applying the different reading voltages to the gate electrode and the second source/drain region and by grounding the first source/drain region. Moreover, the third source/drain region may be grounded while reading the second data bit.

In some embodiments of the invention, the third data bit stored in the charge storage region of the charge trapping layer adjacent to the third source/drain region may be read by applying the different reading voltages to the gate electrode and the first source/drain region and by grounding the third source/drain region. A voltage similar to the reading voltage applied to the first source/drain region may be applied to the second source/drain region while reading the third data bit. The fourth data bit stored in the charge storage region of the charge trapping layer adjacent to the first source/drain region may be read by applying the different reading voltages to the gate electrode and the third source/drain region and by grounding the first source/drain region. Further, the second source/drain region may be grounded while reading the fourth data bit.

In methods according to some embodiments of the invention, the first and the third data bit may be simultaneously programmed by applying a first programming voltage to the gate electrode, by applying second programming voltages to the second and the third source/drain regions, and by grounding the first source/drain region. Furthermore, the second and the fourth data bit may be simultaneously programmed by applying a first programming voltage to the gate electrode, by applying a second programming voltage to the first source/drain region, and by grounding the second and the third source/drain regions.

In some methods according to the invention, the first and the third data bit may be simultaneously read by applying a first reading voltage to the gate electrode, by applying a second reading voltage to the first source/drain region, and by grounding the second and the third source/drain regions. The second and the fourth data bit may be simultaneously read by applying a first reading voltage to the gate electrode, by applying second reading voltages to the second and the third source/drain regions, and by grounding the first source/drain region.

Methods of operating a nonvolatile semiconductor memory device according to some embodiments of the invention include programming a first data bit or a second data bit by applying different programming voltages to a gate electrode, a first source/drain region and a second source/drain region, programming a third data bit or a fourth data bit by applying different programming voltages to the gate electrode, the first source/drain region and a third source/drain region, reading the first data bit or the second data bit by applying different reading voltages to the gate electrode, the first source/drain region and the second source/drain region, reading the third data bit or the fourth data bit by applying different reading voltages to the gate electrode, the first source/drain region and the third source/drain region, and erasing the programmed data bit by applying different erasing voltages to the gate electrode and the substrate. The first, the second and the third source/drain regions may be grounded while erasing the programmed data bit.

### BRIEF DESCRIPTION OF THE DRAWINGS

FIG. 1 is a cross-sectional view illustrating a non-volatile semiconductor memory device in accordance with some embodiments of the invention;

FIG. 2 is an equivalent circuit diagram of the non-volatile semiconductor device illustrated in FIG. 1;

FIG. 3 is a plan view illustrating the non-volatile semiconductor device of FIG. 1;

FIGS. 4 and 5 are cross-sectional views illustrating the programming and reading of a first data bit into and from the nonvolatile semiconductor memory device in FIG. 1 in accordance with some embodiments of the invention;

FIGS. 6 and 7 are cross-sectional views illustrating the programming and reading of a second data bit into and from the nonvolatile semiconductor memory device in FIG. 1 in accordance with some embodiments of the invention;

FIGS. 8 and 9 are cross-sectional views illustrating simultaneously programming and reading a first data bit and a third data bit into and from the nonvolatile semiconductor memory device in FIG. 1 in accordance with some embodiments of the invention;

FIG. 10 is a cross-sectional view illustrating a nonvolatile semiconductor memory device in accordance with an some embodiments of the invention; and

FIGS. 11 to 30 are cross-sectional views and plan views illustrating methods of forming nonvolatile semiconductor memory devices in accordance with some embodiments of the invention.

### DETAILED DESCRIPTION OF EMBODIMENTS OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. Likewise, the term “vertical” refers to the orientation of elements shown in a figure. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

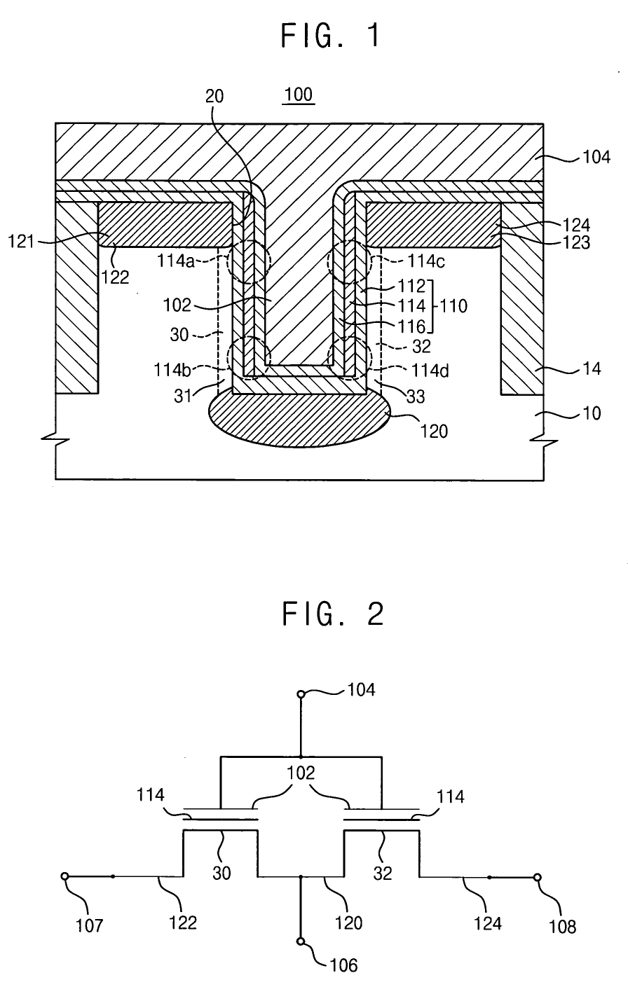

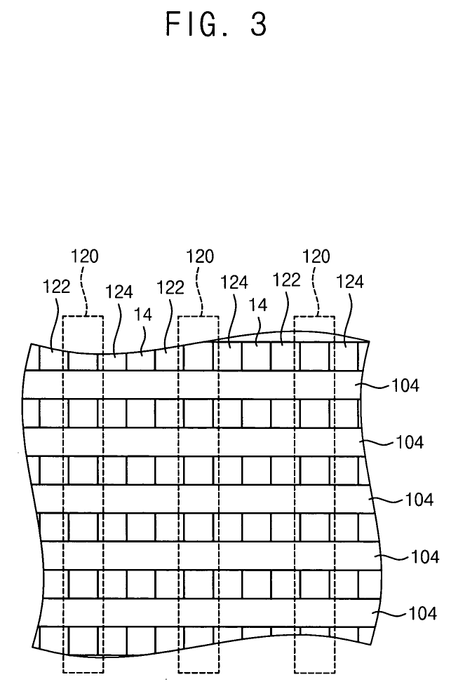

FIG. 1 is a cross-sectional view illustrating a non-volatile semiconductor device 100 in accordance with an some embodiments of the invention. FIG. 2 is an equivalent circuit diagram of the non-volatile semiconductor device 100 in FIG. 1. FIG. 3 is a plan view illustrating the non-volatile semiconductor device 100 in FIG. 1.

Referring to FIGS. 1 to 3, a non-volatile semiconductor device 100 includes a gate electrode 102 formed within a recess 20 on a semiconductor substrate 10. The recess 20 may be formed vertically from a surface of the semiconductor substrate 10. The recess 20 may define an upper portion of the semiconductor substrate 10.

An insulation structure 110 is formed between a sidewall of the gate electrode 102 and a sidewall of the recess 20. At least portions of the insulation structure 110 are also formed between a bottom of the gate electrode 102 and a bottom of the recess 20. That is, the insulation structure 110 may enclose the gate electrode 102 within the recess 20. The insulation structure 110 may further extend onto an upper surface of the semiconductor substrate 10.

A first source/drain region 120 may be formed at a first portion of the semiconductor substrate 10 beneath the portions of the insulation structure 110 within the recess 20. That is, the first source/drain region 120 may be disposed underneath the gate electrode 102 and the recess 20. A second source/drain region 122 and a third source/drain region 124 may be formed at a second portion 121 and a third portion 123, respectively, of the substrate 10 adjacent to the sidewalls of the gate electrode 102. In particular, the second and the third source/drain regions 122 and 124 may be disposed adjacent to a first side of the gate electrode 102 and a second side of the gate electrode 102, respectively. The second and the third source/drain regions 122 and 124 may be separated from the first source/drain region 120.

The gate electrode 102 may be buried in the recess 20. The gate electrode 102 may have a rectangular prism shape that is vertically elongated relative to the surface of the substrate 10. The gate electrode 102 may include polysilicon doped with N type impurities or P type impurities. Alternatively or additionally, the gate electrode 102 may include a metal such as tungsten (W), titanium (Ti), tantalum (Ta), aluminum (Al), copper (Cu), etc., and/or a combination thereof.

The insulation structure 110 includes a first insulation layer 112, a charge trapping layer 114 and a second insulation layer 116. The first insulation layer 112 may serve as a tunnel oxide layer and the second insulation layer 116 may function as a blocking oxide layer. The charge trapping layer 114 may trap electrons therein. The first insulation layer 112 may be formed on the bottom and the sidewall of the recess 20. The first insulation layer 112 may also be formed on the upper face of the semiconductor substrate 10. The charge trapping layer 114 may be formed on a portion of the first insulation layer 112 between the sidewall of the recess 20 and the sidewall of the gate electrode 102. That is, the charge trapping layer 114 may not be positioned on the upper face of the semiconductor substrate 10. While not illustrated in FIG. 1, the charge trapping layer 114 may also be formed between the bottom of the recess 20 and the bottom of the gate electrode 102. The second insulation layer 116 may be formed on the charge trapping layer 114 in the recess 20 and/or the first insulation layer 112 on the upper face of the semiconductor substrate 10.

The first insulation layer 112 may include an oxide such as silicon oxide. The second insulation layer 116 may include an oxide such as silicon oxide or a metal oxide such as aluminum oxide. The charge trapping layer 114 may include silicon nitride, a nano-crystalline material, aluminum oxide, and/or hafnium oxide, either alone or in a mixture thereof. The nano-crystalline material may include silicon (Si), silicon germanium (SiGe), tungsten, cobalt (Co), molybdenum (Mo), cadmium selenium (CdSe), tungsten nitride (WN), etc., either alone or in a combination thereof.

Still referring to the embodiments of FIGS. 1 and 2, the gate electrode 102 may be connected to a word line 104, and may be capacitively coupled to the charge trapping layer 114. In the embodiments illustrated in FIG. 1, the first, the second and the third source/drain regions 120, 122 and 124 are separated from one another. In particular, the second source/drain region 122 and the third source/drain region 124 are centered around the first source/drain region 120. A first channel 30 may be formed between the first source/drain region 120 and the second source/drain region 122, and a second channel 32 may be formed between the first source/drain region 120 and the third source/drain region 124. The first insulation layer 112 may be positioned between the charge trapping layer 114 and the first and the second channels 30, 32 respectively. The gate electrode 102 is electrically isolated from the charge trapping layer 114 by the second insulation layer 116. Additionally, the first, the second and the third source/drain regions 120, 122 and 124 may be electrically connected to first, second and third bit lines 106, 107 and 108, respectively.

As shown in FIG. 2, the gate electrode 102 may serve as a common electrode for a pair of transistor devices 31, 33 defined by the first and second channels 30, 32. The first, second and third source/drain regions 120, 122 and 124 may function as the source/drain regions for the transistors 31, 33. As a result, the nonvolatile semiconductor memory device 100 may include the common gate electrode 102, three source/drain regions 120, 122 and 124 disposed adjacent to the recess 20 to serve as the source/drain region for the transistors 31 and 33, and a charge trapping layer 114 disposed between the gate electrode 102 and the sidewalls of the recess 20. The first insulation layer 112 is disposed between the charge trapping layer 114 and the sidewalls of the recess 20, and the second insulation layer 116 is positioned between the gate electrode 102 and the charge trapping layer 114.

Field isolation patterns 14 may be formed at upper portions of the semiconductor substrate 10 along a first direction that crosses the semiconductor substrate 10. The field isolation patterns 14 may be formed by an isolation process such as a shallow trench isolation (STI) process. The recess 20 may be positioned between adjacent field isolation patterns 14.

As shown in the embodiments of FIG. 1, the first source/drain region 120 may be positioned beneath the lower portion of the gate electrode 102. The first source/drain region 120 may contact the first insulation layer 112. The second and the third source/drain regions 122 and 124 may be spaced apart from the first source/drain region 120 in a vertical direction relative to the substrate 10. The second and the third source/drain regions 122 and 124 may be adjacent to an upper portion of the gate electrode 102. The second and the third source/drain regions 122 and 124 may contact the first insulation layer 122. In particular, the second and the third source/drain regions 122 and 124 may be positioned at upper portions of the substrate 10 between the field isolation patterns 14 and the recess 20.

The first, second and third source/drain regions 120, 122 and 124 may be formed at the first, second and third portions of the substrate 10, for example, by one or more ion implantation processes. That is, impurities may be implanted into the first, second and third portions of the substrate 10 to thereby form the first, second, and third source/drain regions 120, 122 and 124. The substrate 10 may be a P-type substrate, while the first, second and third source/drain regions 120, 122 and 124 may have N-type conductivity, respectively.

The first, second and third source/drain regions 120, 122 and 124 may extend along a first direction perpendicular to the plane of FIG. 1. As illustrated in FIG. 2, the gate electrode 102 is electrically connected to the word line 104, which extends in a second direction that is substantially perpendicular to the first direction. The first, the second and the third source/drain regions 120, 122 and 124 may be electrically connected to one another through the first, the second and the third bit lines 106, 107 and 108, and conductive plugs (not shown).

Each of the first, second and third source/drain regions 120, 122 and 124 may serve as one of the source/drain regions of the transistors 31 and 33 in accordance with voltages applied to the word line 104 and the bit lines 106, 107 and 108. When a programming voltage is applied to the gate electrode 102 and one of the source/drain regions 120, 122 and 124 so as to program (i.e., write) data in the nonvolatile semiconductor memory device 100, a channel may be induced in the region of the substrate adjacent to a first side of the recess 20 between the first source/drain region 120 and the second source/drain region 122, and/or adjacent to a second side of the recess 20 between the first source/drain region 120 and the third source/drain region 124. When the programming voltages are applied to the gate electrode 102 and the first source/drain region 120, and the second and the third source/drain regions 122 and 124 are grounded, the first source/drain region 120 may function as the drain region. Additionally, the first and the second channels 30 and 32 are generated adjacent to the first and the second sides of the recess 20, respectively. Furthermore, the electrons may move from the second and the third source/drain regions 122 and 124 toward the first source/drain region 120 through the first and the second channels 30 and 32.

According to some embodiments of the invention, the charge trapping layer 114 may serve as a data storage layer for the nonvolatile semiconductor memory device 100. The charge trapping layer 114 is disposed between the gate electrode 102 and the sides of the recess 20.

The charge trapping layer 114 may include a first charge storage region 114a, a second charge storage region 114b, a third charge storage region 114c, and a fourth charge storage region 114d. The first and the second charge storage regions 114a and 114b are adjacent to the first channel 30. The third and the fourth charge storage regions 114c and 114d are adjacent the second channel 32. For example, the first charge storage region 114a may be disposed adjacent to the first channel 30 near the second source/drain region 122, and the second charge storage region 114b may be positioned adjacent to the first channel 30 near the first source/drain region 120. Additionally, the third charge storage region 114c may be formed adjacent to the second channel 32 near the third source/drain region 124, and the fourth charge storage region 114d may be adjacent with the second channel 32 near the first source/drain region 120. In the embodiments illustrated in FIG. 1, the first, second, third and fourth charge storage regions 114a, 114b, 114c and 114d are identified by circles with dotted lines.

As electrons move through the first and the second channels 30 and 32, some of the electrons may have sufficient energy to jump the potential barrier of the first insulation layer 112 and become trapped in trap sites in the charge trapping layer 114. For example, when the first source/drain region 120 is grounded and the programming voltages are applied to the gate electrode 102 to the second source/drain region 122, electrons move from the first source/drain region 120 to the second source/drain region 122 through the first channel 30. Some of the electrons may be injected into the first charge storage region 114a near the second source/drain region 122. Therefore, the threshold voltage of the first channel 30 in a region adjacent to the first charge storage region 114a may be reduced.

The first, second, third and fourth charge storage regions 114a, 114b, 114c and 114d can store one bit of data each, so that a nonvolatile semiconductor memory device 100 according to some embodiments of the invention may store up to four bits of data. In particular, each of the first, second, third and fourth charge storage regions 114a, 114b, 114c and 114d may store a logic state of ‘0’ or ‘1’ (i.e., a binary value of ‘0’ or ‘1’). When each of the first, second, third and fourth charge storage regions 114a, 114b, 114c and 114d is programmed (for example, the logic state is ‘0’), a first channel current may be relatively low. On the other hand, a second channel current may be relatively high when each of the first, second, third and fourth charge storage regions 114a, 114b, 114c and 114d is unprogrammed (for example, the logic state is ‘1’). In order to distinguish the logic state (i.e., ‘0’ or ‘1’) of a charge storage region, it may be desirable to increase the difference between the first and the second channel currents.

The amount of charge injected into the charge trapping layer 114 may vary in accordance with the programming time (i.e. the amount of time for which a programming voltage is applied), and the threshold voltage of the channel may vary by the amount of the trapped charges. When the programming time is exceedingly long, the time needed for removing the trapped charges from the charge trapping layer 114 may also be longer, thereby reducing the erasing efficiency of the nonvolatile semiconductor device 100. However, the data stored in the charge trapping layer 114 may be read along a direction opposed to the direction in which the electrons move while programming the nonvolatile semiconductor device 100. Thus, the programming time may be reduced.

When the first charge storage region 114a is programmed in a first positive direction, the data stored in the first charge storage region 114a may be advantageously read along a first negative direction opposite the first positive direction because the threshold voltage of the first channel 30 during reading of the data in the first negative direction may be higher than the threshold voltage of the first channel 30 during reading of the data along the first positive direction. In some embodiments of the invention, electrons move through the first channel 30 along the first positive direction while programming the first charge storage region 114a. The first negative direction is substantially opposite the first positive direction.

When the first source/drain region 120 is grounded and programming voltages are applied to the gate electrode 102 and the second source/drain region 122 so as to read the data stored in the first charge storage region 114a along the first positive direction, the threshold voltage of the first channel 30 may be relatively low because electric fields caused by reading voltages may be most strong adjacent to the second source/drain region 122. When the second source/drain region 122 is grounded, and the reading voltages are applied to the gate electrode 102 and the first source/drain region 120 in order to read the data stored in the first charge storage region 114a along the first negative direction, the electric fields caused by the reading voltages may be relatively low near the second source/drain region 122, so that the threshold voltage of the first channel 30 may be relatively high. For example, the threshold voltage of the first channel 30 may be above about 4V when reading data along the first negative direction, whereas the threshold voltage of the first channel 30 may be below about 1V when reading the data along the first positive direction. Thus, in order to easily detect a current difference between the logic states of ‘0’ and ‘1’, the data may be read along the first negative direction. The reading of data stored in the nonvolatile semiconductor memory device along a positive direction and a negative direction is described, for example, in U.S. Pat. No. 6,649,972.

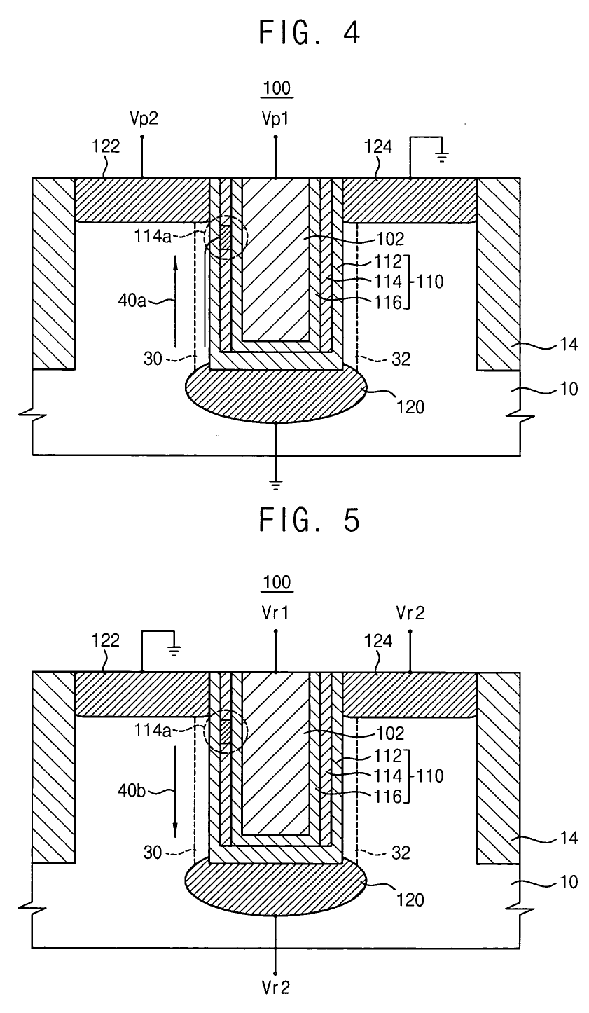

FIGS. 4 and 5 are cross-sectional views illustrating the programming and reading of a first data bit into and from the nonvolatile semiconductor memory device 100 in FIG. 1 according to some embodiments of the invention.

Referring to the embodiments of FIG. 4, a first data bit is stored in the first charge storage region 114a along a first positive direction 40a. In particular, programming voltages Vp1 and Vp2 are applied to the gate electrode 102 and the second source/drain region 122, respectively, and the first and the third source/drain regions 120 and 124 are grounded. For example, a programming voltage Vp1 of about 10V may be applied to the gate electrode 102, and a programming voltage Vp2 of about 5V may be applied to the second source/drain region 122. Due to the application of the programming voltage Vp1 to the gate electrode 102, the first channel 30 is formed between the first source/drain region 120 and the second source/drain region 122. In response to the programming voltage Vp2 applied to the second source/drain region 122, electrons move from the first source/drain region 120 to the second source/drain region 122 through the first channel 30. Some of the electrons passing through the first channel 30 may be injected into the first charge storage region 114a. The charge trapped in the first charge storage region 114a is shown as a hatched portion in FIG. 4.

Although the second channel 32 may be formed between the first source/drain region 120 and the third source/drain region 124, the electrons may not travel through the second channel 32 because the first and the third source/drain regions 120 and 124 are grounded.

Referring to the embodiments of FIG. 5, to read the first data bit stored in the first charge storage region 114a along a first negative direction 40b, reading voltages Vr1 and Vr2 are applied to the gate electrode 102 and the first source/drain region 120, respectively, and the second source/drain region 122 is grounded. The reading voltage Vr2 applied to the first source/drain region 120 may also be applied to the third source/drain region 124 so as to substantially prevent current from flowing through the second channel 32. In some embodiments, a reading voltage Vr1 of about 3V may be applied to the gate electrode 102, and the reading voltage Vr2 of about 2V may be applied to the first source/drain region 120.

When the first charge storage region 114a has a logic state of ‘0’, the current of the first channel 30 may be relatively low. On the other hand, the current of the first channel 30 may be relatively high when the first charge storage region 114a has a logic state of ‘1’. In particular, when the first charge storage region 114a has the logic state of ‘0’, electric charge trapped in the first charge storage region 114a may increase the threshold voltage of the first channel 30 adjacent to the first charge storage region 114a so that the current of the first channel 30 may become relatively low. However, while reading the first data bit in the first charge storage region 114a along the first positive direction 40a, the logic state of the first charge storage region 114a may not be read precisely, because the threshold voltage of the first channel 30 may be below about 1V and the current of the first channel 30 may be relatively high.

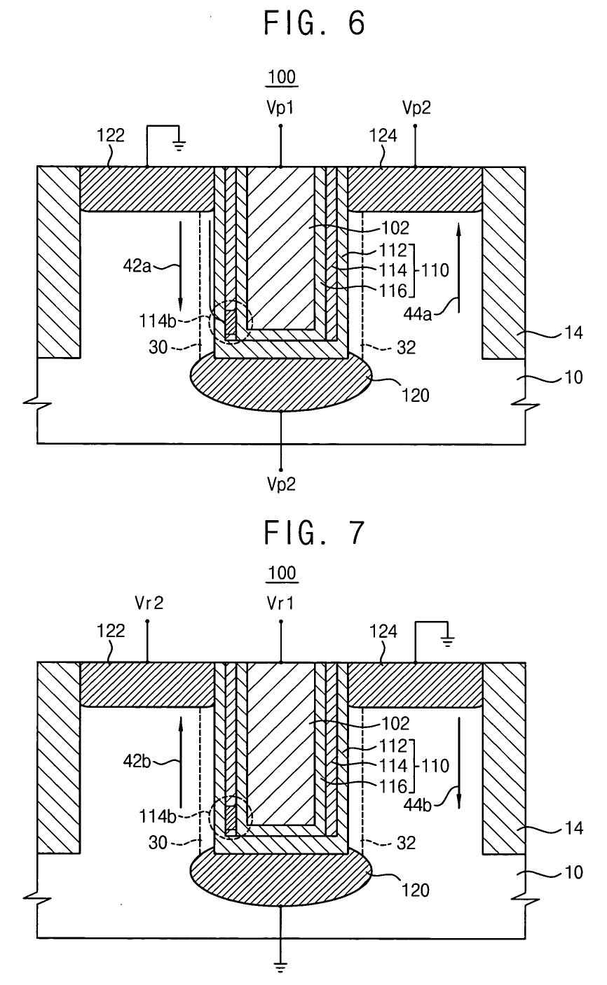

FIGS. 6 and 7 are cross-sectional views illustrating the programming and reading of a second data bit into and from the nonvolatile semiconductor memory device 100 in FIG. 1 according to some embodiments of the invention.

Referring to the embodiments of FIG. 6, a second data bit may be stored in the second charge storage region 114b along a second positive direction 42a. In particular, programming voltages Vp1 and Vp2 may be applied to the gate electrode 102 and the first source/drain region 120 respectively, and the second source/drain region 122 may be grounded. In some embodiments, a programming voltage Vp1 of about 10V may be applied to the gate electrode 102, and a programming voltage Vp2 of about 5V may be applied to the first source/drain region 120. Thus, the first channel 30 may be formed between the first source/drain region 120 and the second source/drain region 122 due to the application of the programming voltage Vp1 to the gate electrode 102. Consequently, electrons travel from the second source/drain region 122 to the first source/drain region 120 through the first channel 30. As they travel through the first channel 30, some of the electrons may be injected into the second charge storage region 114b. The charge trapped in the second charge storage region 114b is shown as a hatched portion in FIG. 6.

The programming voltage Vp2 may also be applied to the third source/drain region 124 to substantially prevent current from flowing in the second channel 32. Therefore, although a second channel 32 may be formed between the first source/drain region 120 and the third source/drain region 124 by the application of the programming voltage Vp1 to the gate electrode 102, current may not flow through the second channel 32.

Referring to the embodiments of FIG. 7, to read the second data bit stored in the second charge storage region 114b along a second negative direction 42b, reading voltages Vr1 and Vr2 may be applied to the gate electrode 102 and the second source/drain region 122, respectively, and the first source/drain region 120 may be grounded. The third source/drain region 124 may be grounded to impede the flow of current through the second channel region 32. For example, a reading voltage Vr1 of about 3V may be applied to the gate electrode 102, and a reading voltage Vr2 of about 2V may be applied to the first source/drain region 120.

A third data bit may be stored in the third charge storage region 114c along a third positive direction 44a. In particular, programming voltages may be applied to the gate electrode 102 and the third source/drain region 124, and the first and the second source/drain regions 120 and 122 may be grounded. For example, a programming voltage of about 10V may be applied to the gate electrode 102, and a programming voltage of about 5V may be applied to the third source/drain region 124. Hence, the second channel 32 may be formed between the first source/drain region 120 and the third source/drain region 124 by the application of a programming voltage to the gate electrode 102. Due to the application of the programming voltage to the third source/drain region 124, electrons flow from the first source/drain region 120 toward the third source/drain region 124 through the second channel 32. As they flow through the second channel 32, some of the electrons may be injected into the third charge storage region 114c.

Although the first channel 30 may be formed between the first source/drain region 120 and the second source/drain region 122, current may not substantially flow through the second channel 32 because the first and the second source/drain regions 120 and 122 are grounded.

To read the third data bit stored in the third charge storage region 114c along a third negative direction 44b, reading voltages may be applied to the gate electrode 102 and the first source/drain region 120, and the third source/drain region 124 may be grounded. The reading voltage applied to the first source/drain region 120 may also be applied to the second source/drain region 122 to impede the flow of current through the first channel 30. For example, a reading voltage of about 3V may be applied to the gate electrode 102, and a reading voltage of about 2V may be applied to the first source/drain region 120.

A fourth data bit may be stored in the fourth charge storage region 114d along a fourth positive direction. In particular, programming voltages may be applied to the gate electrode 102 and the first source/drain region 120, respectively, and the third source/drain region 124 may be grounded. For example, a programming voltage of about 10V may be applied to the gate electrode 102, and a programming voltage of about 5V may be applied to the first source/drain region 120. The second channel 32 may be formed between the first source/drain region 120 and the third source/drain region 124 due to the application of the programming voltage to the gate electrode 102. Due to the application of the programming voltage to the first source/drain region 120, electrons move from the third source/drain region 124 to the first source/drain region 120 through the second channel 32. As they flow through the second channel 32, some of the electrons may be injected into the fourth charge storage region 114d.

The programming voltage applied to the first source/drain region 120 may also be applied to the second source/drain region 122. Although the first channel 30 may be formed between the first source/drain region 120 and the second source/drain region 122 by the programming voltage applied to the gate electrode 102, current may not flow through the first channel 30 because the additional voltage and the programming voltage are applied to the first and the second source/drain regions 120 and 122, respectively.

To read the fourth data bit stored in the fourth charge storage region 114d along a fourth negative direction, reading voltages may be applied to the gate electrode 102 and the third source/drain region 124, respectively, and the first source/drain region 120 may be grounded. The second source/drain region 122 may also be grounded to substantially prevent current from flowing through the first channel 30. For example, a reading voltage of about 3V may be applied to the gate electrode 102, and a reading voltage of about 2V may be applied to the third source/drain region 124.

The voltages used for programming and reading of the first, second, third and fourth data bits are summarized in Table 1, below.

TABLE 1

| | | First | Second | Third |
|---|---|---|---|---|
| | Gate | Source/drain | Source/drain | Source/drain |
| | Electrode | region | region | region |
| Programming the | Vp1 | Grounded | Vp2 | Grounded |
| First Data bit | | | | |
| Programming the | Vp1 | Vp2 | Grounded | Vp2 |
| Second Data Bit | | | | |
| Programming the | Vp1 | Grounded | Grounded | Vp2 |
| Third Data Bit | | | | |
| Programming the | Vp1 | Vp2 | Vp2 | Grounded |
| Fourth Data Bit | | | | |
| Reading the First | Vr1 | Vr2 | Grounded | Vr2 |
| Data Bit | | | | |
| Reading the | Vr2 | Grounded | Vr2 | Grounded |
| Second Data Bit | | | | |
| Reading the Third | Vr3 | Vr2 | Vr2 | Grounded |
| Data Bit | | | | |
| Reading the | Vr4 | Grounded | Grounded | Vr2 |
| Fourth Data Bit | | | | |

As shown in Table 1, four data bits can be stored in the first, second, third and fourth charge storage regions 114a, 114b, 114c and 114d, respectively, by properly adjusting the programming voltages and the reading voltages applied to the gate electrode 102 and the first, second and third source/drain regions 120, 122 and 124.

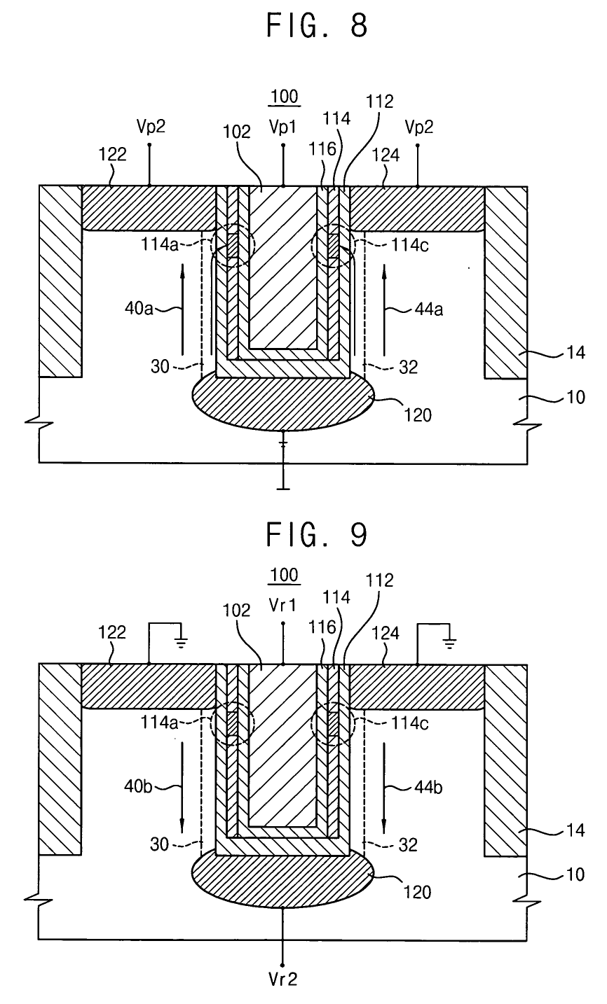

FIGS. 8 and 9 are cross-sectional views illustrating the simultaneous programming and reading of a first data bit and a third data bit into and from the nonvolatile semiconductor memory device 100 in FIG. 1.

Referring to the embodiments of FIG. 8, the first and the third data bits may be simultaneously programmed into the first and the third charge storage regions 114a and 114c along the first and the third positive directions 40a and 44a. In particular, the first source/drain region 120 may be grounded, and a programming voltage Vp1 may be applied to the gate electrode 102. A programming voltage Vp2 may be applied to the second source/drain region 122 and the third source/drain region 124. For example, a programming voltage Vp1 of about 10V may be applied to the gate electrode 102, and a programming voltage Vp2 may be applied to the second and the third source/drain regions 122 and 124. Accordingly, the first and the second channels 30 and 32 may be formed by the programming voltage Vp1 applied to the gate electrode 102, and electrons may move from the first source/drain region 120 to the second and the third source/drain regions 122 and 124 through the first and the second channels 30 and 32 due to the application of the programming voltage Vp2 to the second and third source/drain regions 122 and 124. Some of the electrons passing through the first and second channels 30 and 32 may be injected into the first and the third charge storage regions 114a and 114c, respectively.

Referring to the embodiments of FIG. 9, the first and the third data bits may be simultaneously read from the first and the third charge storage regions 114a and 114c along the first and the third negative directions 40b and 44b, respectively, by applying the reading voltages Vr1 and Vr2 to the gate electrode 102 and the first source/drain region 120, respectively, and grounding the second and the third source/drain regions 122 and 124. For example, when the first charge storage region 114a has the logic state of ‘0’ and the third charge storage region 114c has the logic state of ‘1’, a reading voltage Vr1 of about 3V may be applied to the gate electrode 102 and a reading voltage Vr2 of about 2V may be applied to the first source/drain region 120. In addition, the second and the third source/drain regions 122 and 124 may be grounded. Accordingly, the channel current of the first channel 30 between the first and the second source/drain regions 120 and 122 may be relatively low, whereas the channel current of the second channel 32 between the first and the third source/drain regions 120 and 124 may be relatively high.

The second and the fourth data bits may be simultaneously programmed into the second and the fourth charge storage regions 114b and 114d along the second and the fourth positive directions by applying appropriate programming voltages to the gate electrode 102 and the first source/drain region 120 and grounding the second and the third source/drain regions 122 and 124. Additionally, the second and the fourth data bit may be simultaneously read from the second and the fourth charge storage regions 114b and 114d along the second and the fourth negative directions by applying appropriate reading voltages to the gate electrode 102, the second source/drain region 122 and the third source/drain region 124, and grounding the first source/drain region 120.

The voltages used for the simultaneous programming and reading of the first, second, third and fourth data bit are summarized in Table 2, below.

TABLE 2

| | | First | Second | Third |
|---|---|---|---|---|
| | Gate | Source/drain | Source/drain | Source/drain |
| | Electrode | region | region | region |
| Programming the | Vp1 | Grounded | Vp2 | Vp2 |
| First Data Bit | | | | |
| Programming the | | | | |
| Third Data Bit | | | | |
| Programming the | Vp1 | Vp2 | Grounded | Grounded |
| Second Data Bit | | | | |
| Programming the | | | | |
| Fourth Data Bit | | | | |
| Reading the First | Vr1 | Vr2 | Grounded | Grounded |
| Data Bit | | | | |
| Reading the Third | | | | |
| Data Bit | | | | |
| Reading the | Vr1 | Grounded | Vr2 | Vr2 |
| Second Data Bit | | | | |
| Reading the | | | | |
| Fourth Data Bit | | | | |

As shown in Table 2, two data bits can be stored into the nonvolatile semiconductor memory device 100 by simultaneously programming two of the first, second, third and fourth charge storage regions 114a, 114b, 114c and 114d.

Additionally, two data bits can be read from the nonvolatile semiconductor memory device 100 by simultaneously reading two of the first, second, third and fourth charge storage regions 114a, 114b, 114c and 114d. Thus, a nonvolatile semiconductor memory device according to some embodiments of the invention may have greatly improved operational characteristics.

In some embodiments of the invention, data bits stored in the first, second, third and fourth charge storage regions 114a, 114b, 114c and 114d may be erased from the first, second, third and fourth charge storage regions 114a, 114b, 114c and 114d by applying erasing voltages to the gate electrode 102, the first source/drain region 120, the second source/drain region 122 and the third source/drain region 124, respectively.

In particular, a negative erasing voltage may be applied to the gate electrode 102, and positive erasing voltages may be applied to the first, second and third source/drain regions 120, 122 and 124 in order to erase the data bits from the nonvolatile semiconductor memory device 100. For example, a negative erasing voltage of about −8V may be applied to the gate electrode 102, and a positive erasing voltage of about 5V may be applied to the first, second and third source/drain regions 120, 122 and 124. Thus, electrons trapped in the first, second, third and fourth charge storage regions 114a, 114b, 114c and 114d may flow to the first, second and third source/drain regions 120, 122 and 124 adjacent to the first, second, third and fourth charge storage regions 114a, 114b, 114c and 114d, respectively. The magnitude of the erasing voltages may vary depending on the thickness of the insulation structure 110. In particular, the erasing voltages may vary based on the thickness of the first insulation layer 112.

In some embodiments of the invention, data bits may be erased from the first, second, third and fourth charge storage regions 114a, 114b, 114c and 114d by grounding the gate electrode 102 and by applying a relatively high erasing voltage, for example, about 13V, to the first, second and third source/drain regions 120, 122 and 124, respectively.

In further embodiments of the invention, erasing voltages may be applied to the gate electrode 102 and the semiconductor substrate 10 in order to erase the data. In particular, a negative erasing voltage may be applied to the gate electrode 102, and a positive erasing voltage may be applied to the semiconductor substrate 10, thereby erasing the data from the nonvolatile semiconductor memory device 100 using the F-N tunneling mechanism. For example, a negative erasing voltage of about −8V may be applied to the gate electrode 102 and a positive erasing voltage of about 12V may be applied to the semiconductor substrate 10 so that the data bit may be erased from the nonvolatile semiconductor memory device 100.

In further embodiments of the invention, the data bit may be erased from the nonvolatile semiconductor memory device 100 by grounding the gate electrode 102 and by applying an erasing voltage of about 20V to the semiconductor substrate 10. In these embodiments, the first, second and third source/drain regions 120, 122 and 124 are grounded.

FIG. 10 is a cross-sectional view illustrating a nonvolatile semiconductor memory device 200 in accordance with further embodiments of the invention.

Referring to the embodiments of FIG. 10, the nonvolatile semiconductor memory device 200 includes a gate electrode 202 formed vertically in a recess 20 at an upper portion of a semiconductor substrate 10. The semiconductor substrate 10 may include a silicon wafer and/or an SOI substrate.

An insulation structure 210 may be positioned between the gate electrode 202 and the recess 20. In particular, the insulation structure 210 may be formed between a sidewall of the recess 20 and a side face of the gate electrode 202, and between a bottom face of the gate electrode 202 and a bottom of the recess 20.

A first source/drain region 220 may be formed at a first portion of the substrate 10 beneath the recess 20. A second source/drain region 222 is positioned at a second portion of the substrate 10 adjacent to a first side of the recess 20, and a third source/drain region 224 is positioned at a third portion of the substrate 10 adjacent to a second side of the recess 20. The second and the third source/drain regions 222 and 224 are separated from the first source/drain region 220.

The insulation structure 210 may include a first insulation layer 212, a charge trapping layer 214 and a second insulation layer 216. The first insulation layer 212 may serve as a tunnel oxide layer, and the second insulation layer 216 may function as a blocking oxide layer. The charge trapping layer 214 may be formed continuously between the first insulation layer 212 and the second insulation layer 216.

When a programming voltage or a reading voltage is applied to the gate electrode 202 through a word line 204 formed on the gate electrode 202, a first channel 30 may be generated between the first and the second source/drain regions 220 and 222, and a second channel 32 may be formed between the first and the third source/drain regions 220 and 224.

The charge trapping layer 214 may include a first charge storage region 214a, a second charge storage region 214b, a third charge storage region 214c and a fourth charge storage region 214d. The first charge storage region 214a may be adjacent to the first channel 30 and the second source/drain region 222, and the second charge storage region 214b may be positioned adjacent to the first channel 30 and the first source/drain region 220. In addition, the third charge storage region 214c may be positioned adjacent to the second channel 32 and the third source/drain region 224, and the fourth charge storage region 214d may be adjacent to the second channel 32 and the first source/drain region 220.

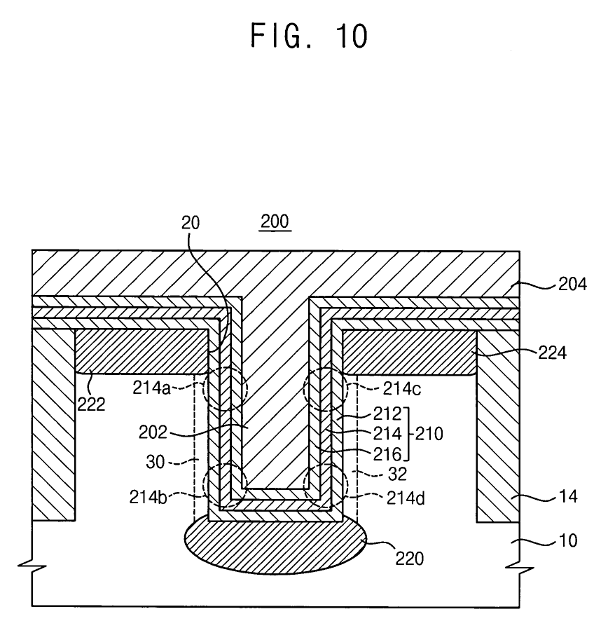

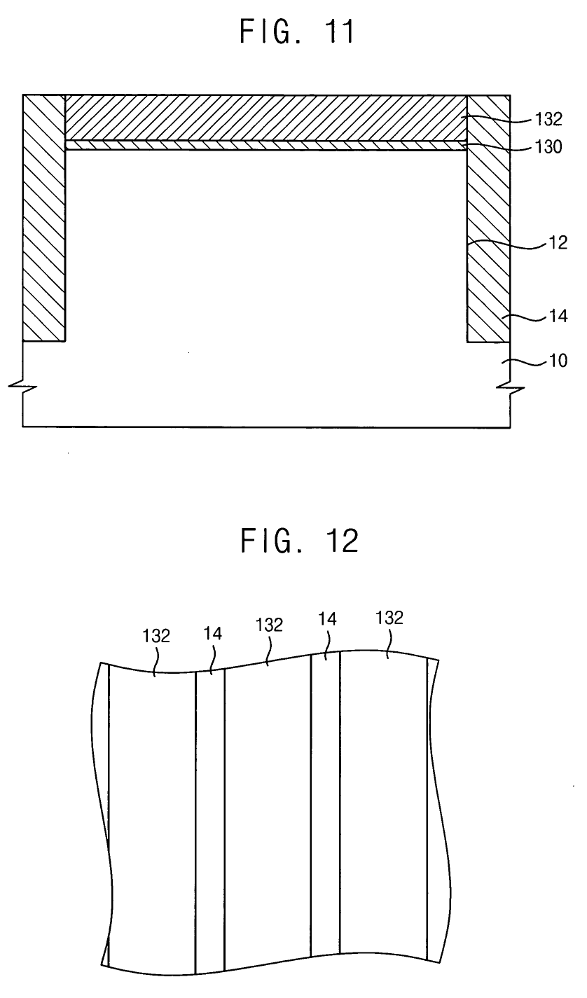

FIGS. 11 to 22 are cross-sectional views and plan views illustrating methods of forming nonvolatile semiconductor memory devices in accordance with some embodiments of the invention. FIGS. 11, 13, 15, 16, 18, 19, 21 and 22 are cross-sectional views illustrating methods of forming nonvolatile semiconductor memory devices, and FIGS. 12, 14, 17 and 20 are plan views illustrating methods of forming nonvolatile semiconductor memory devices.

Referring to the embodiments of FIGS. 11 and 12, first trenches 12 may be formed at an upper portion of a semiconductor substrate 10 along a first direction crossing the semiconductor substrate 10. The semiconductor substrate 10 may include a silicon wafer and/or an SOI substrate. Field isolation patterns 14 may be formed to fill up the first trenches 12, respectively.

In some embodiments of the invention, a first pad oxide layer 130 may be formed on the substrate 10. The first pad oxide layer 130 may be formed by a chemical vapor deposition (CVD) process and/or a thermal oxidation process. A first mask layer (not shown) may be formed on the first pad oxide layer 130. The first mask layer may be formed using a nitride such as silicon nitride. For example, the first mask layer may be formed using an SiH₂Cl₂ gas, an SiH₄ gas and/or an NH₃ gas. Additionally, the first mask layer may be formed by a low pressure chemical vapor deposition (LPCVD) process and/or a plasma enhanced chemical vapor deposition (PECVD) process.

After a first photoresist pattern (not shown) is formed on the first mask layer, the first mask layer may be anisotropically etched using the first photoresist pattern as an etching mask, thereby forming a first mask pattern 132 on the first pad oxide layer 130. The first photoresist pattern may be removed by an ashing process and/or a stripping process.

As illustrated in FIG. 11, the first trenches 12 may be formed by partially etching the first pad oxide layer 130 and the semiconductor substrate 10 using the first mask pattern 132 as an etching mask. The first trenches 12 may have a depth of about 1,000 Å to about 5,000 Å. For example, the first trenches 12 may have a depth of about 2,300 Å.

In some embodiments of the invention, an oxidation process may be performed on sidewalls of the first trenches 12 to repair etch damage to the substrate 10 generated in the etching process of forming the first trenches 12 and to reduce leakage current generated through the first trenches 12. When the sidewalls of the first trenches 12 are oxidized, trench oxide layers may be formed on the sidewalls of the first trenches 12. In some embodiments, the trench oxide layers may have a thickness of about 30 Å.

Afield isolation layer (not shown) may be formed on the substrate 10 to fill up the first trenches 12. The field isolation layer may be formed using an oxide such as silicon oxide. For example, the field isolation layer may be formed using undoped silicate glass (USG), spin on glass (SOG), tetraethylorthosilcate (TEOS), plasma enhanced-tetraethylorthosilcate (PE-TEOS), high density plasma-chemical vapor deposition (HDP-CVD) oxide, etc., either alone or in combination. When the field isolation layer is formed using HDP-CVD oxide, an SiH₄ gas, an O₂ gas and an Ar gas may be used as process gases.

The first mask pattern 132 may be exposed when the field isolation layer is partially etched so that the field isolation patterns 14 may be formed in the first trenches 12. The field isolation patterns 14 may be formed by a chemical mechanical polishing (CMP) process, an etch back process and/or a combination process of CMP and etch back.

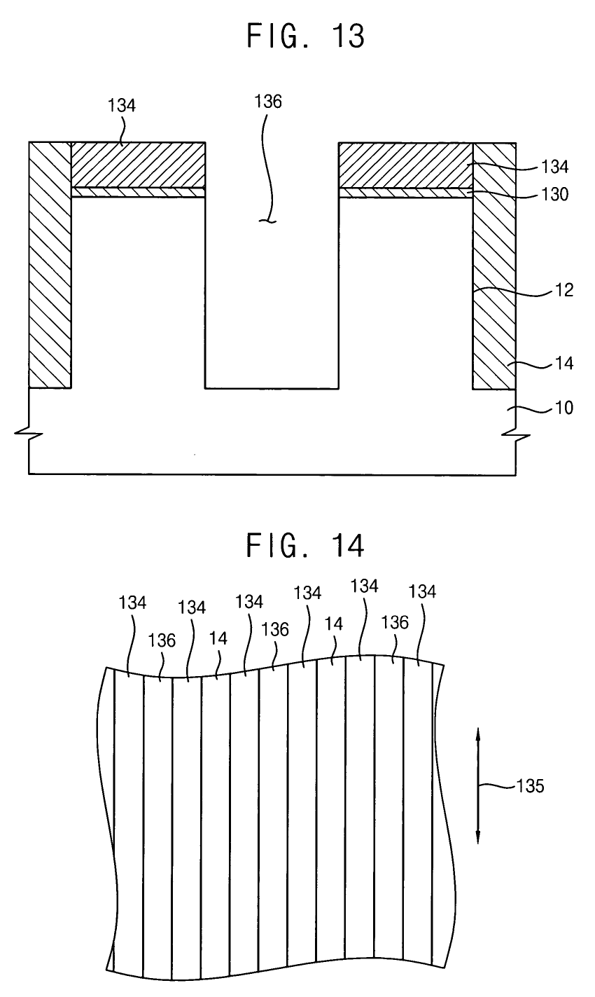

Referring to the embodiments of FIGS. 13 and 14, a second trench 136 may be formed between the first trenches 12. After a second photoresist pattern (not shown) is formed on the first mask pattern 132 and the field isolation patterns 14, the first mask pattern 132 is partially etched using the second photoresist pattern as an etching mask. Thus, a second mask pattern 134 may be formed to expose portions of the first pad oxide layer 130 between the field isolation patterns 14. The first mask pattern 132 may be etched, for example, by an anisotropic etching process. The second photoresist pattern may be removed, for example, by an ashing process and/or a stripping process.

Using the second mask pattern 134 as an etching mask, the first pad oxide layer 130 and upper portions of the substrate 10 may be anisotropically etched so that the second trenches 136 are formed at the upper portions of the substrate 10 along the first direction 135.

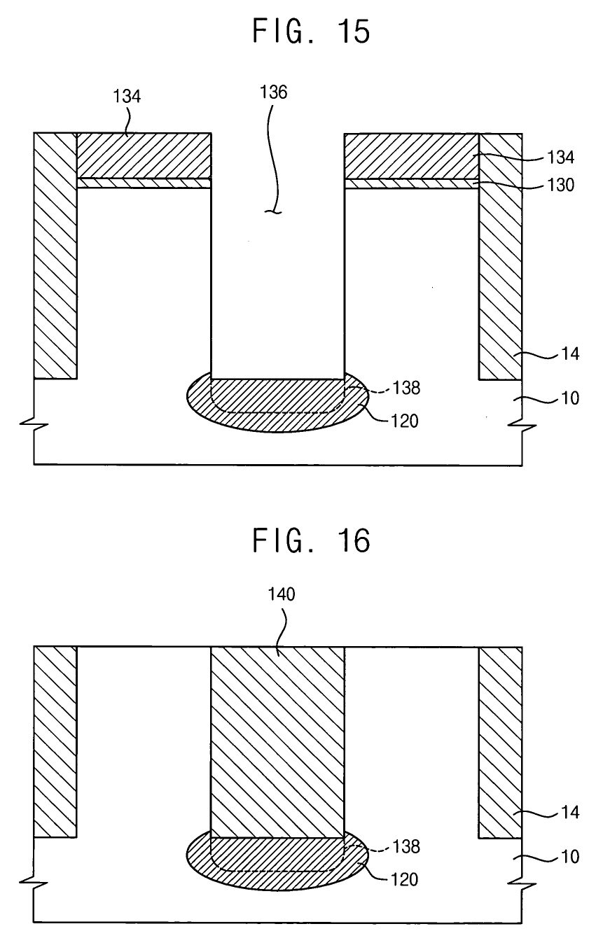

Referring to the embodiments of FIG. 15, a preliminary first doped region 138 may be formed at a first portion of the substrate 10 adjacent to a bottom of the second trench 136, for example, by an ion implantation process. For example, the preliminary first source/drain region 138 may be formed by implanting N-type impurities into the first portion of the substrate 10 using the second mask pattern 134 as an implantation mask. When the preliminary first source/drain region 138 is formed, the impurities may be implanted into the substrate 10 at an angle of about 90° (i.e., normal to the substrate 10) to reduce the implantation of impurities into the sides of the second trench 136.

In some embodiments of the invention, a second pad oxide layer (not shown) may be formed on the sides of the second trench 136 and a bottom of the second trench 136 before forming the preliminary first source/drain region 138. The second pad oxide layer may protect the second trench 136 in successive processes.

In some embodiments of the invention, the second trench 136 may be enlarged by an isotropic etching process to remove impurities unintentionally implanted into the sides of the second trench 136.

The impurities implanted into the first portion of the substrate 10 may be thermally annealed to form a first source/drain region 120 extending along the first direction 135. In some embodiments, the first source/drain region 120 may be annealed at a temperature of above about 600° C.

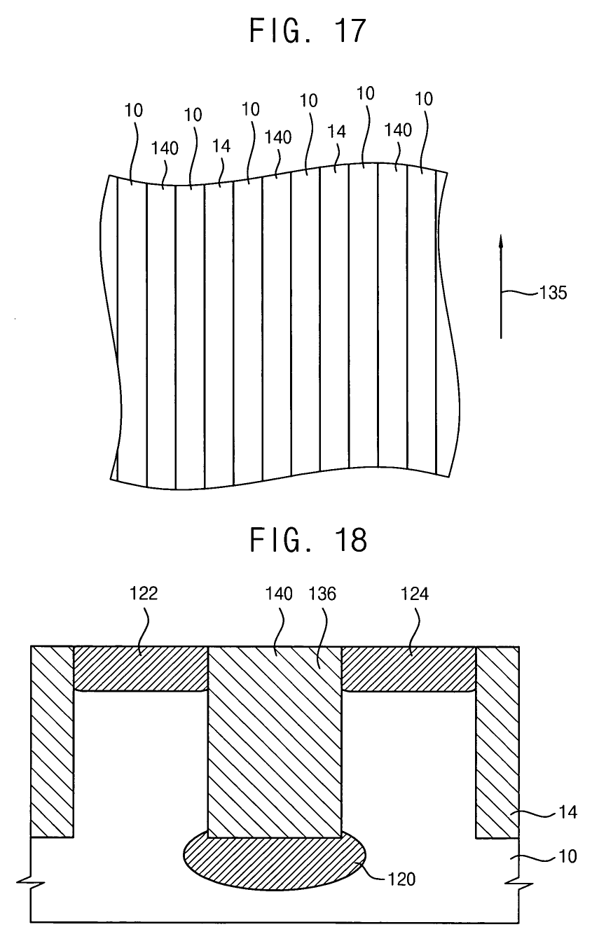

Referring to the embodiments of FIGS. 16 and 17, after removing the second mask pattern 134, a sacrificial layer (not shown) may be formed on the substrate 10 to fill up the second trench 136. The second mask pattern 134 may be removed, for example, using an etching solution that contains phosphoric acid. The sacrificial layer may be formed using a material similar to that of the field isolation layer 14.

The sacrificial layer and the first pad oxide layer 130 may be partially etched until the substrate 10 is exposed so that a sacrificial layer pattern 140 may be formed in the second trench 136. The sacrificial layer pattern 140 may be formed by a CMP process, an etch back process and/or a combination process of CMP and etch back. When the sacrificial layer pattern 140 is formed by a CMP process, a surface of the substrate 10 may serve as a polishing stop layer.

In some embodiments of the invention, the second mask pattern 134 may be removed in the process of forming the sacrificial layer pattern 140 without any additional processing.

Referring to the embodiments of FIG. 18, a second source/drain region 122 and a third source/drain region 124 may be formed at a second portion and a third portion of the substrate 10. The second and the third doped regions 122 and 124 may extend along the first direction 135. Each of the second and the third source/drain regions 122 and 124 may be formed between the sacrificial layer pattern 140 and the field isolation patterns 14. The second and the third source/drain regions 122 and 124 may be adjacent to an upper portion of the second trench 136. The second and the third source/drain regions 122 and 124 may be formed, for example, by an ion implantation process. The second and the third source/drain regions 122 and 124 may also be formed using N-type impurities, respectively. That is, the semiconductor substrate 10 may have a P-type conductivity, and the first, second and third source/drain regions 120, 122 and 124 may have N-type conductivities.

An annealing process may be performed on the substrate 10 to repair damage to the substrate 10 that may occur in the process of forming the second and the third source/drain regions 122 and 124.

In some embodiments of the invention, a third pad oxide layer may be formed on the substrate 10 to protect the substrate 10 in the process of forming the second and the third source/drain regions 122 and 124 before forming the second and the third source/drain regions 122 and 124.

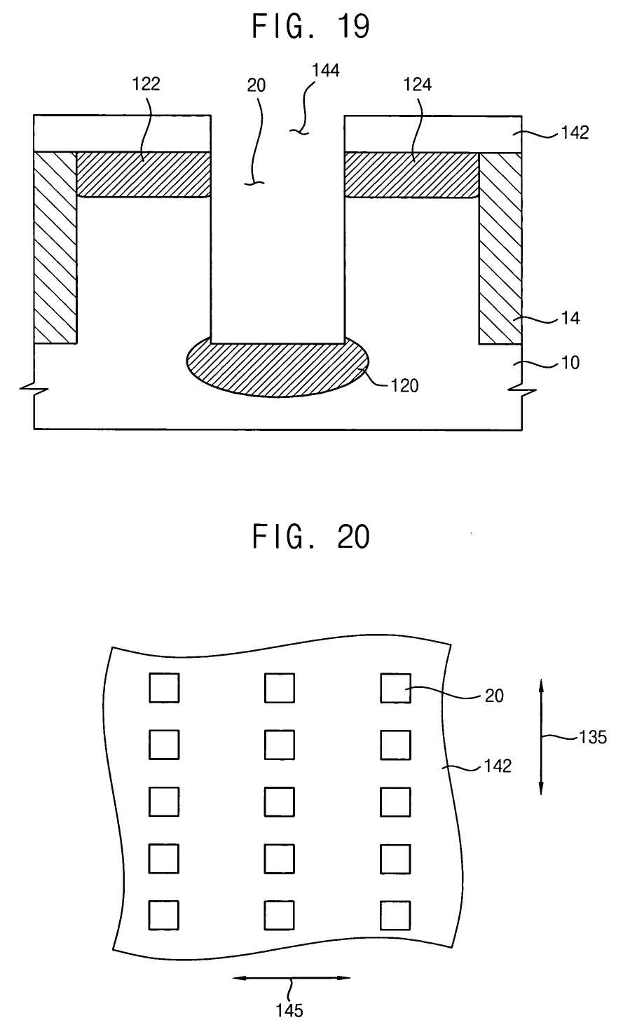

Referring to the embodiments of FIGS. 19 and 20, a third photoresist pattern 142 may be formed on the field isolation patterns 14, the second source/drain region 122, the third source/drain region 124 and the sacrificial layer pattern 140. The third photoresist pattern 142 may partially expose the sacrificial layer pattern 140. In particular, the third photoresist pattern 142 may have an opening 144 that exposes the sacrificial layer pattern 140 along a second direction 145 substantially perpendicular to the first direction 135.

The sacrificial layer pattern 140 may be partially etched using the third photoresist pattern 142 as an etching mask to thereby form a recess 20 that partially exposes the bottom and the sides of the second trench 136. The recess 20 may be formed vertically at the upper portion of the substrate 10. The recess 20 may be formed, for example, by anisotropically etching a portion of the sacrificial layer pattern 140. The third photoresist pattern 142 may be removed, for example, by an ashing process and/or a stripping process.

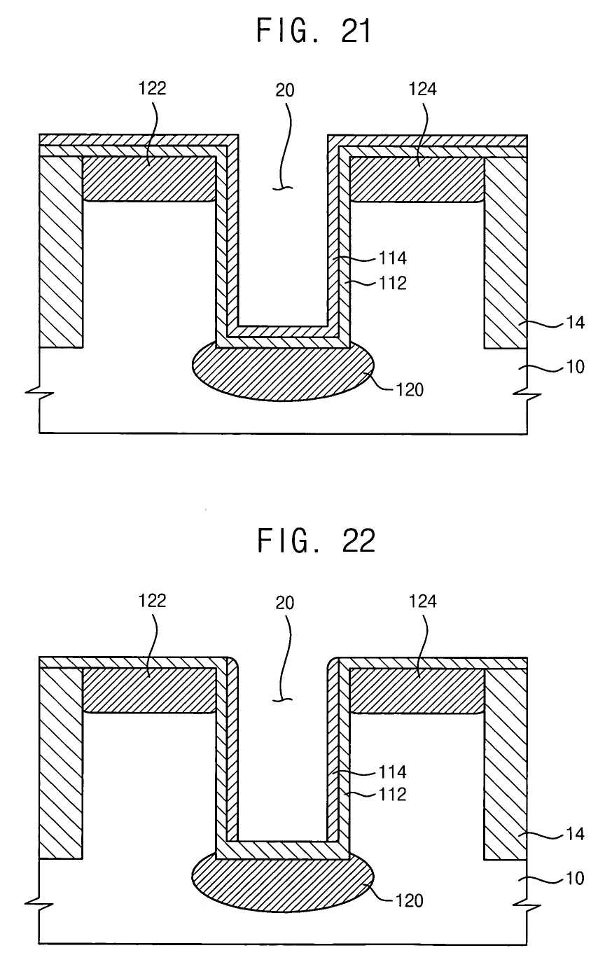

Referring to the embodiments of FIG. 21, a first insulation layer 112 and a charge trapping layer 114 may be formed sequentially on the bottom and sides of the recess 20. The first insulation layer 112 may be formed using an oxide such as silicon oxide. The first insulation layer 112 may be formed by a thermal oxidation process to have a thickness of about 50 Å to about 100 Å. The charge trapping layer 114 may be formed using a nitride and/or a metal oxide such as silicon nitride, aluminum nitride and/or hafnium oxide, either alone or in a mixture thereof. Alternatively, the charge trapping layer 114 may be formed using a nano-crystalline material such as silicon, silicon germanium, tungsten, cobalt, molybdenum, cadmium selenium or tungsten nitride, either alone or in a mixture thereof.

Referring to the embodiments FIG. 22, portions of the charge trapping layer 114 may be etched from the first, second and third source/drain regions 120, 122 and 124 so that the charge trapping layer 114 may remain on the sides of the recess 20 only. The charge trapping layer 114 may be partially etched, for example, by an anisotropic etching process.

An oxidization process may be carried out to repair damage to the first insulation layer 112 generated in the etching process of partially etching the charge trapping layer 114.

A second insulation layer 116 may be formed on the charge trapping layer 114 and the first insulation layer 112 as shown in FIGS. 1 to 3. The second insulation layer 116 may be formed using an oxide and/or a metal oxide. For example, the second insulation layer 116 may be formed using silicon oxide and/or aluminum oxide. The second insulation layer 116 may be formed by an LPCVD process and/or an atomic layer deposition (ALD) process. The second insulation layer 116 may have a thickness of about 50 Å to about 100 Å.

After a conductive layer (not shown) is formed on the second insulation layer 116 to fill up the recess 20, the conductive later may be patterned to form a gate electrode 102 and a word line 104. The gate electrode 102 may fill up the recess 20. The word line 104 may be formed on the gate electrode 102 along the second direction. The conductive layer may be formed using a conductive material such as metal and/or polysilicon doped with impurities. The conductive layer may be formed by an LPCVD process, an ALD process, a physical vapor deposition (PVD) process, a sputtering process, a pulse laser deposition (PLD) process, and/or a metal organic chemical vapor deposition (MOCVD) process, etc.

In some embodiments of the invention, after a fourth photoresist pattern is formed on the conductive layer along the second direction, the conductive layer may be partially etched using the fourth photoresist pattern as an etching mask to thereby from the gate electrode 102 and the word line 104. The fourth photoresist pattern may be removed, for example, by an ashing process and/or a stripping process.

In some embodiments of the invention, after an insulation interlayer is formed on the word line 104, the insulation interlayer may be partially etched to form contact holes that expose the first, second and third source/drain regions 120, 122 and 124, respectively. Plugs may be formed to fill up the contact holes, and then a first to a third bit line 106, 107 and 108 may be formed on the plugs. The first to the to the third bit lines 106, 107 and 108 may be electrically connected to the first, second and third source/drain regions 120, 122 and 124, respectively.

In some embodiments of the invention, the charge trapping layer 114 may be continuously formed between the first insulation layer 112 and the second insulation layer 116 without partially etching the charge trapping layer 114 as shown in FIG. 10.

In some embodiments of the invention, a nonvolatile semiconductor memory device may include a gate electrode recessed at an upper portion of a substrate, and four charge storage regions for storing four data bits. Thus, a nonvolatile semiconductor memory device according to some embodiments of the invention may have reduced physical dimensions, thereby enabling greater device integration. In addition, a nonvolatile semiconductor memory device according to some embodiments of the invention may have an enhanced response time because two data bits may be simultaneously programmed into the charge storage regions and simultaneously read from the charge storage regions.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. A nonvolatile semiconductor memory device, comprising:
a substrate having a trench therein, the trench having sidewalls and a bottom;
a gate electrode in the trench;
a plurality of source/drain regions in the substrate adjacent to the gate electrode;
a pair of channel regions in the substrate extending along the sidewalls of the trench between respective pairs of adjacent source/drain regions;
a charge trapping layer disposed between the gate electrode and the channel regions; and
a first insulation layer between the charge trapping layer and the channel regions.

2. The device of claim 1, wherein the source/drain regions comprise:
a first source/drain region beneath the trench;
a second source/drain region adjacent to a first side of the trench and vertically separated from the first source/drain region; and
a third source/drain region adjacent to a second side of the trench and vertically separated from the first source/drain region.

3. The device of claim 2, wherein the pair of channel regions comprises a first channel between the first source/drain region and the second source/drain region, and a second channel between the first source/drain region and the third source/drain region, and wherein the charge trapping layer comprises a plurality of charge storage regions.

4. The device of claim 1, further comprising a second insulation layer between the gate electrode and the charge trapping layer.

5. A nonvolatile semiconductor memory device, comprising:
a substrate having a recess therein, the recess having a bottom and a pair of opposing sides;
a first source/drain region in the substrate beneath the recess;
a second source/drain region and a third source/drain region in the substrate, the second source/drain region and the third source/drain region disposed on the opposing sides of the recess and spaced apart from the first source/drain region;
an insulation structure on the bottom and the opposing sides of the recess, the insulation structure comprising a first insulation layer, a second insulation layer, and a charge trapping layer between the first insulation layer and the second insulation layer; and
a gate electrode on the insulation structure.

6. The device of claim 5, further comprising a first channel in the substrate between the first and the second source/drain regions, and a second channel in the substrate between the first and the third source/drain regions.

7. The device of claim 6, wherein the charge trapping layer comprises two charge storage regions adjacent to the first channel, and two charge storage regions adjacent to the second channel.

8. The device of claim 7, wherein the charge trapping layer comprises:
a first charge storage region adjacent to the first channel and the second source/drain region;
a second charge storage region adjacent to the first channel and the first source/drain region;
a third charge storage region adjacent to the second channel and the third source/drain region; and
a fourth charge storage region adjacent to the second channel and the first source/drain region.

9. The device of claim 5, wherein the charge trapping layer is at least partially positioned between the opposing sides of the recess and the gate electrode.

10. The device of claim 5, wherein the charge trapping layer extends down a first side of the recess, along the bottom of the recess, and up a second side of the recess.

11. The device of claim 5, wherein the gate electrode has a rectangular prism structure that extends vertically in relation to a surface of the substrate.

12. The device of claim 5, wherein the first insulation layer comprises silicon oxide.

13. The device of claim 5, wherein the second insulation layer comprises silicon oxide or aluminum oxide.

14. The device of claim 5, wherein the charge trapping layer comprises silicon nitride, a nano-crystalline material, aluminum oxide and/or hafnium oxide.

15. The device of claim 14, wherein the nano-crystalline material comprises silicon, silicon germanium, tungsten, cobalt, molybdenum, cadmium selenium and/or tungsten nitride.

16. The device of claim 5, wherein the substrate has a P-type conductivity, the first source/drain region has an N-type conductivity, the second source/drain region has an N-type conductivity, and the third source/drain region has an N-type conductivity.

17. The device of claim 5, wherein the gate electrode comprises metal and/or polysilicon doped with impurities.

18. A nonvolatile semiconductor memory device comprising:
a gate electrode;
a plurality of source/drain regions disposed adjacent to the gate electrode;
a channel between an adjacent pair of source/drain regions;
a charge trapping layer disposed between the gate electrode and the channel, the charge trapping layer configured to trap electrons passing through the channel; and
a first insulation layer between the charge trapping layer and the channel.

19. The device of claim 1, wherein the gate electrode is vertically buried at an upper portion of a substrate and wherein the source/drain regions comprise a first source/drain region adjacent to a lower portion of the gate electrode, a second source/drain region adjacent to a first side of the gate electrode and vertically separated from the first source/drain region, and a third source/drain region adjacent to a second side of the gate electrode and vertically separated from the first source/drain region.

20. A method of forming a nonvolatile semiconductor memory device, comprising:
forming a recess having opposing sidewalls and a bottom in a substrate;
forming a first source/drain region beneath the recess;
forming a second source/drain region and a third source/drain region at an upper portion of the substrate on the opposing sidewalls of the recess and spaced apart from the first source/drain region;
forming an insulation structure on the bottom and the opposing sidewalls of the recess, the insulation structure comprising a first insulation layer, a second insulation layer on the first insulation layer, and a charge trapping layer between the first and the second insulation layers; and
forming a gate electrode on the insulation structure.

21. The method of claim 20, wherein forming the recess comprises:
forming a mask pattern on the substrate, the mask pattern including an opening therein exposing a portion of the substrate; and
anisotropically etching the exposed portion of the substrate using the mask pattern as an etching mask.

22. The method of claim 21, wherein forming the first source/drain region comprises implanting impurities into a region of the substrate beneath the recess using the mask pattern as an implantation mask.

23. The method of claim 22, further comprising isotropically etching the substrate after forming the first source/drain region.

24. The method of claim 21, wherein forming the recess comprises:
removing the mask pattern;
forming a sacrificial layer on the substrate to fill up the recess; and
partially removing the sacrificial layer until the substrate is exposed.

25. The method of claim 24, wherein the second and the third source/drain regions are formed by implanting impurities into the substrate after partially removing the sacrificial layer.

26. The method of claim 20, wherein forming the insulation structure comprises:
forming the first insulation layer on the bottom and the opposing sides of the recess;
forming the charge trapping layer on the first insulation layer; and
forming the second insulation layer on the charge trapping layer.

27. The method of claim 26, further comprising removing a portion of the charge trapping layer formed at the bottom of the recess.

28. The method of claim 27, wherein removing a portion of the charge trapping layer comprises anisotropically etching the charge trapping layer, and wherein the method further comprises oxidizing the first insulation layer to repair damage to the first insulation layer caused by anisotropically etching the charge trapping layer.

29. The method of claim 20, wherein the first insulation layer is formed using silicon oxide.

30. The method of claim 20, wherein the second insulation layer is formed using silicon oxide and/or aluminum oxide.

31. The method of claim 20, wherein the charge trapping layer is formed using silicon nitride, a nano-crystalline material, aluminum oxide and/or hafnium oxide.

32. The method of claim 31, wherein the nano-crystalline material comprises silicon, silicon germanium, tungsten, cobalt, molybdenum, cadmium selenium and/or tungsten nitride.

33. The method of claim 20, wherein the substrate has a P-type conductivity, the first source/drain region has an N-type conductivity, the second source/drain region has an N-type conductivity, and the third source/drain region has an N-type conductivity.

34. The method of claim 20, wherein the gate electrode is formed using metal and/or polysilicon doped with impurities.

35. A method of operating a nonvolatile semiconductor memory device having a substrate, a trench at an upper portion of the substrate, a gate electrode disposed in the trench, a charge trapping layer positioned between the gate electrode and sidewalls of the trench, an insulation layer positioned between the charge trapping layer and the sidewalls of the trench, a first source/drain region beneath the trench, a second source/drain region disposed adjacent to an upper portion of the insulation layer on a first side of the trench and separated from the first source/drain region, and a third source/drain region disposed adjacent to an upper portion of the insulation layer on a second side of the trench opposite the first side of the trench and separated from the first source/drain region, the method comprising:
programming a first data bit or a second data bit by applying different programming voltages to the gate electrode, the first source/drain region and the second source/drain region;
programming a third data bit or a fourth data bit by applying different programming voltages to the gate electrode, the first source/drain region and the third source/drain region;
reading the first data bit or the second data bit by applying different reading voltages to the gate electrode, the first source/drain region and the second source/drain region;
reading the third data bit or the fourth data bit by applying different reading voltages to the gate electrode, the first source/drain region and the third source/drain region; and
erasing the programmed data bit by applying a first erasing voltage to the gate electrode and a second erasing voltage to the first source/drain region, the second source/drain region and the third source/drain region.

36. The method of claim 35, wherein the first data bit is programmed into a charge storage region of the charge trapping layer adjacent to the second source/drain region by applying the different programming voltages to the gate electrode and the second source/drain region and by grounding the first source/drain region.

37. The method of claim 36, wherein the third source/drain region is grounded while programming the first data bit.

38. The method of claim 35, wherein the second data bit is programmed into a charge storage region of the charge trapping layer adjacent to the first source/drain region by applying the different programming voltages to the gate electrode and the first source/drain region and by grounding the second source/drain region.

39. The method of claim 38, wherein a voltage similar to the programming voltage applied to the first source/drain region is applied to the third source/drain region while programming the second data bit.

40. The method of claim 35, wherein the third data bit is programmed into a charge storage region of the charge trapping layer adjacent to the third source/drain region by applying the different programming voltages to the gate electrode and the third source/drain region and by grounding the first source/drain region.

41. The method of claim 40, wherein the second source/drain region is grounded while programming the third data bit.

42. The method of claim 35, wherein the fourth data bit is programmed into a charge storage region of the charge trapping layer adjacent to the first source/drain region by applying the different programming voltages to the gate electrode and the first source/drain region and by grounding the third source/drain region.

43. The method of claim 42, wherein a voltage similar to the programming voltage applied to the first source/drain region is applied to the second source/drain region while programming the fourth data bit.

44. The method of claim 35, wherein the first data bit stored in the charge storage region of the charge trapping layer adjacent to the second source/drain region is read by applying the different reading voltages to the gate electrode and the first source/drain region and by grounding the second source/drain region.

45. The method of claim 44, wherein a voltage similar to the reading voltage applied to the first source/drain region is applied to the third source/drain region while reading the first data bit.

46. The method of claim 35, wherein the second data bit stored in the charge storage region of the charge trapping layer adjacent to the first source/drain region is read by applying the different reading voltages to the gate electrode and the second source/drain region and by grounding the first source/drain region.

47. The method of claim 46, wherein the third source/drain region is grounded while reading the second data bit.

48. The method of claim 35, wherein the third data bit stored in the charge storage region of the charge trapping layer adjacent to the third source/drain region is read by applying the different reading voltages to the gate electrode and the first source/drain region and by grounding the third source/drain region.

49. The method of claim 48, wherein a voltage similar to the reading voltage applied to the first source/drain region is applied to the second source/drain region while reading the third data bit.

50. The method of claim 35, wherein the fourth data bit stored in the charge storage region of the charge trapping layer adjacent to the first source/drain region is read by applying the different reading voltages to the gate electrode and the third source/drain region and by grounding the first source/drain region.

51. The method of claim 50, wherein the second source/drain region is grounded while reading the fourth data bit.

52. The method of claim 35, wherein the first and the third data bit are simultaneously programmed by applying a first programming voltage to the gate electrode, by applying a second programming voltage to the second and the third source/drain regions, and by grounding the first source/drain region.

53. The method of claim 35, wherein the second and the fourth data bit are simultaneously programmed by applying a first programming voltage to the gate electrode, by applying a second programming voltage to the first source/drain region, and by grounding the second and the third source/drain regions.

54. The method of claim 35, wherein the first and the third data bit are simultaneously read by applying a first reading voltage to the gate electrode, by applying a second reading voltage to the first source/drain region, and by grounding the second and the third source/drain regions.

55. The method of claim 35, wherein the second and the fourth data bit are simultaneously read by applying a first reading voltage to the gate electrode, by applying second reading voltages to the second and the third source/drain regions, and by grounding the first source/drain region.

56. A method of operating a nonvolatile semiconductor memory device having a substrate, a trench at an upper portion of the substrate, a gate electrode disposed in the trench, a charge trapping layer positioned between the gate electrode and sidewalls of the trench, an insulation layer positioned between the charge trapping layer and the sidewalls of the trench, a first source/drain region beneath the trench, a second source/drain region disposed adjacent to an upper portion of the insulation layer on a first side of the trench and separated from the first source/drain region, and a third source/drain region disposed adjacent to an upper portion of the insulation layer on a second side of the trench opposite the first side of the trench and separated from the first source/drain region, the method comprising:
programming first data bit or second data bit by applying different programming voltages to the gate electrode, the first source/drain region and the second source/drain region;
programming third data bit or fourth data bit by applying different programming voltages to the gate electrode, the first source/drain region and the third source/drain region;
reading the first data bit or the second data bit by applying different reading voltages to the gate electrode, the first source/drain region and the second source/drain region;
reading the third data bit or the fourth data bit by applying different reading voltages to the gate electrode, the first source/drain region and the third source/drain region; and
erasing the programmed data bit by applying different erasing voltages to the gate electrode and the substrate.

57. The method of claim 56, wherein the first, the second and the third source/drain regions are grounded while erasing the programmed data bit.
